(19) United States
(12) Patent Application Publication
(10) Pub. No.: US 2008/0077840 A1
(43) Pub. Date: Mar. 27, 2008

(54) MEMORY SYSTEM AND METHOD FOR STORING AND CORRECTING DATA

(76) Inventors: Mark Shaw, Richardson, TX (US); Larry J. Thayer, Fort Collins, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/535,776

(22) Filed: Sep. 27, 2006

(51) Int. Cl. G11C 29/00

(52) U.S. Cl. 714/763

(57) ABSTRACT

A data memory system is provided which includes a plurality of first data storage devices, at least two second data storage devices, and a third data storage device. The plurality of first data storage devices is configured to store first data. The second data storage devices are configured to store error correction data. Also included in the system is a control circuit configured to generate the error correction data using the first data, correct errors in the first data using the error correction data, and replace one of the plurality of first data storage devices or one of the at least two second data storage devices with the third data storage device.

### BACKGROUND

Enabling the ongoing improvement in both functionality and performance of electronic devices has been the progressive increase in capacity and access speed of digital memory systems. For example, individual memory components such as static random access memories (SRAMs) and dynamic random access memories (DRAMs), as well as modules containing several memory components, such as single in-line memory modules (SIMMs) and dual in-line memory modules (DIMMs), currently provide many megabytes of digital data storage in small packages. These advancements in memory technology allow vast amounts of data storage to be incorporated in cell phones, personal digital assistants (PDAs), global positioning system (GPS) receivers, and other portable electronic products.

However, increases in digital memory capacity also intensify any difficulties associated with maintaining the integrity of the data stored in the memory. Data errors of either a temporary or permanent nature may occur with significant frequency, depending on the nature of the specific memory device and associated product involved. For example, DRAMs are well-known for experiencing temporary data errors in random locations during normal operation. Unfortunately, a data error of just a single binary digit (or “bit”) within a memory component can often cause an unrecoverable error in the associated product, the generation of corrupted and unusable data, or other significant maladies.

As a result, preserving data integrity within a digital memory is often a high priority in electronic systems. To this end, many data error detection and correction schemes for digital data memories have been devised which are capable of correcting one or more erroneous data bits per memory location. However, such schemes typically involve costs in terms of increased complexity and data storage overhead. Accordingly, the more powerful the error detection and correction scheme, the greater the associated costs incurred. In addition, such capability becomes more important and costly as the capacity of the digital data memories being employed continues to increase.

### BRIEF DESCRIPTION OF THE DRAWINGS

FIG. 1 is a block diagram of a data memory system according to an embodiment of the invention.

FIG. 2 is a flow diagram of a method for storing and correcting data in a data memory system according to an embodiment of the invention.

FIG. 3 is a block diagram of a data memory system according to another embodiment of the invention.

FIG. 4 is a block diagram of the data organization of an addressable location of the data memory system of FIG. 3 according to an embodiment of the invention.

FIG. 5 is a flow diagram of a method for storing and correcting data in the memory data system of FIG. 3 according to an embodiment of the invention.

### DETAILED DESCRIPTION

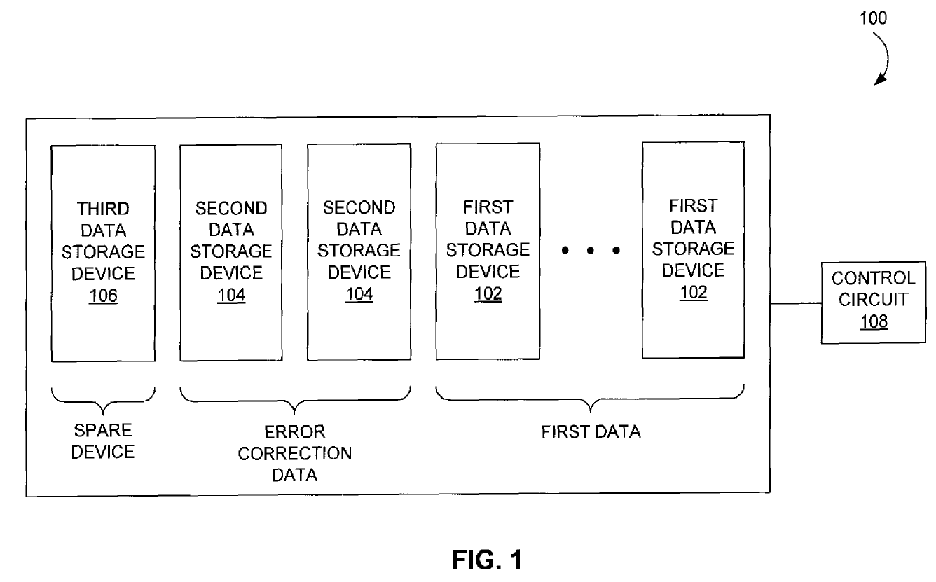

One embodiment of the invention is a data memory system 100 as shown in FIG. 1. Included in the memory system 100 are a plurality of first data storage devices 102, at least two second data storage devices 104, and a third data storage device 106. The plurality of first data storage devices 102 are configured to store first data, which may include user data. The second data storage devices 104 are configured to store error correction data. The third data storage device 106 is provided as a spare device for replacing one of the first data storage devices 102 or one of the at least two second data storage devices 104.

Also provided in the data memory system 100 is a control circuit 108 configured to generate the error correction data using the first data. In addition, the control circuit 108 is configured to correct an error in the first data using the error correction data. Furthermore, the control circuit 108 is configured to replace one of the first data storage devices 102 or one of the at least two second data storage devices 104 with the third data storage device 106.

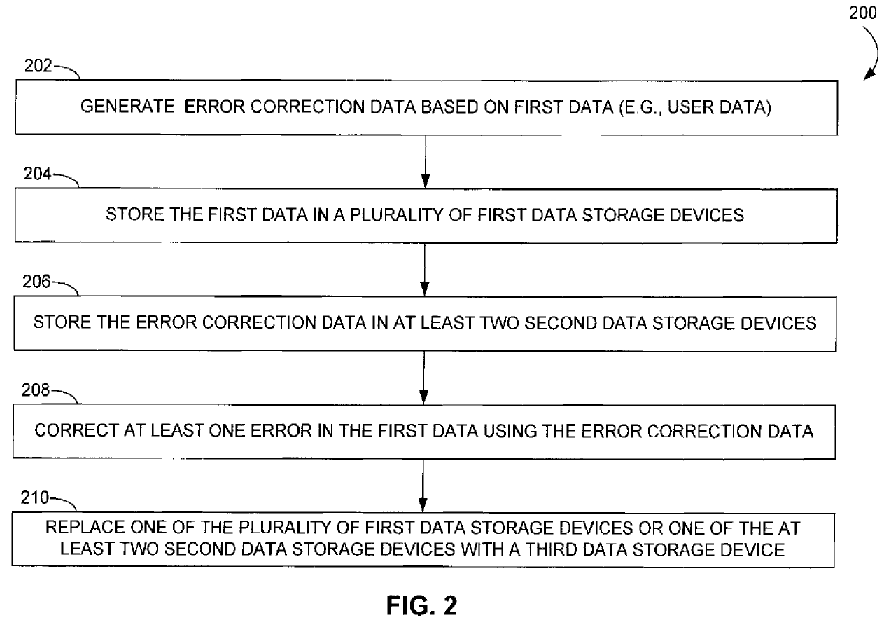

FIG. 2 displays a method 200 for storing and correcting data in a data memory system. The method 200 is described in conjunction with the memory system 100 of FIG. 1, although the method 200 may also be implemented with respect to other memory structures. First, error correction data is generated based on first data (operation 202). In one embodiment, the first data includes user data. The first data is then stored in a plurality of the first data storage devices 102 (operation 204). Also, the error correction data is stored in at least two second data storage devices 104 (operation 206). At least one error in the first data is corrected using the error correction data (operation 208). In addition, one of the plurality of first data storage devices 102 or one of the at least two second data storage devices 104 is replaced by the third data storage device 106 (operation 210).

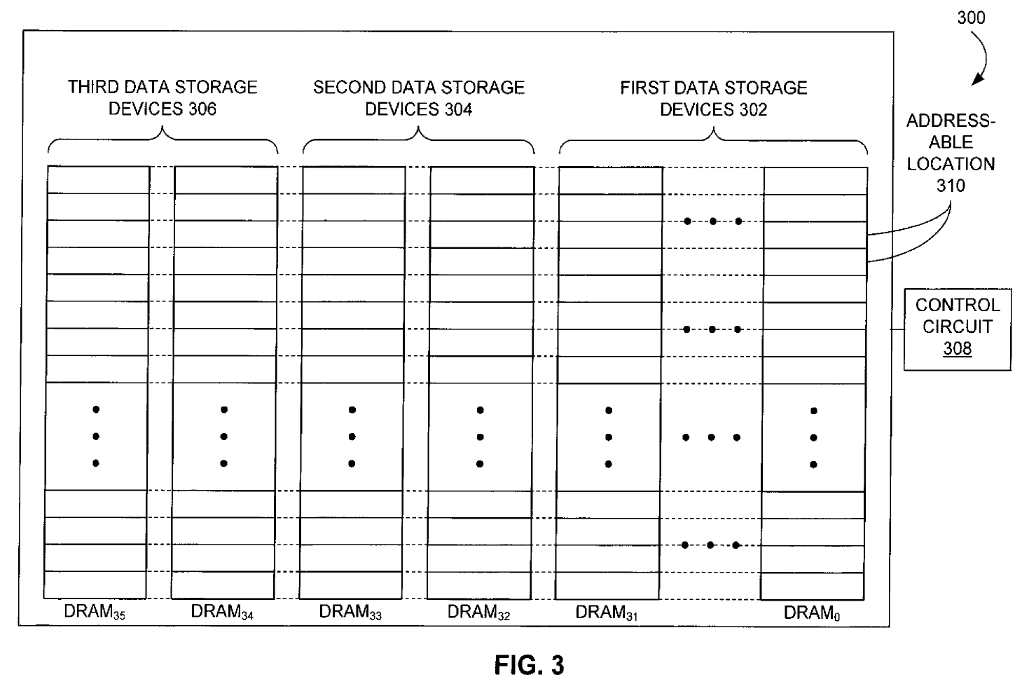

FIG. 3 depicts a particular data memory system 300 according to another embodiment of the invention. While the data memory system 300 is described below in specific terms, such as number of memory devices, specific data organization, possible types of error correction employed, and the like, other embodiments employing variations of the details specified below are also possible.

The system 300 includes several first data storage devices 302, two second data storage devices 304, and two third data storage devices 306. In the particular embodiment of FIG. 3, the data storage devices 302, 304, 306 are 16-bit-wide dynamic random access memories (DRAMs). In other implementations, other widths of DRAMs, such 8 bits or 4 bits, may be employed. Used in still other embodiments are other types of memory devices and structures of varying bit widths, such as static random-access memories (SRAMs), and larger memory configurations utilizing a number of such devices, including, but not limited to, single in-line memory modules (SIMMs), dual in-line memory modules (DIMMs), and fully-buffered dual in-line memory modules (FBDs).

In the particular example of FIG. 3, a total of 36 DRAMs are employed: 32 DRAMs (DRAM₃₁-DRAM₀) as first data storage devices 302, two DRAMs (DRAM₃₂ and DRAM₃₃) as second data storage devices 304, and two DRAMs (DRAM₃₄ and DRAM₃₅) as third data storage devices 306. While the memory configuration shown in FIG. 3 specifically employs 16-bit-wide DRAMs, other implementations using other memory device bit widths, such as 8 bits and 4 bits, are possible. For example, a number of standard Joint Electron Device Engineering Council (JEDEC) memory configurations, such as two single-rank DIMMs carrying 18 4-bit-wide DRAMs, or four single-rank DIMMs with 9 8-bit-wide DRAMs, thus each involving 36 separate memory devices, may be employed in the embodiments described in conjunction with FIG. 3 below. The use of multiple DDR DIMMs in other embodiments is also contemplated.

In the embodiment of FIG. 3, the first data storage devices 302 are configured to store user data. User data, or “payload” data, is the data sought to be stored to, and ultimately retrieved from, the memory system 300. In other implementations, the first data storage devices 302 may also include, for example, control or status information related to the user data. Such control or status information may be of interest only within the data memory system 300. The error correction data is derived from the user data, and is employed to detect and correct errors in the user data, along with any other data stored in the first data storage devices 302. The second data storage devices 304 are configured to store error correction data for the user data and other information within the first data storage devices 302. Two data storage devices 304 are employed to hold error correction data because a rule-of-thumb of many error correction algorithms is that an addressable location of erroneous user data requires twice that number of bits of error correction data for complete correction. For example, to correct a completely erroneous location of a 4-bit-wide DRAM, 8-bits of error correction data associated with that location should be employed. Each of the user data and the error correction data is described in greater detail below.

While 36 DRAMs are employed in the specific example of FIG. 3, different numbers of data storage devices may be used for each of the first data storage devices 302, second data storage devices 304, and third data storage devices 306 in other embodiments. For example, more or fewer DRAMs may be used as first data storage devices 302 to alter data capacity. Similarly, more than two second data storage devices 304 may be employed to increase error correction capability, and more than two third data storage devices 306 may be incorporated to increase the ability to replace more than one of the first data storage devices 302 or the second data storage devices 304. In other implementations, extra third data storage devices 306 may be used instead for system-related information, such as coherency directory information, extra error correction information, and the like. In another example, only one third data storage device 306 may be employed strictly as a spare.

Each of the data storage devices 302 includes separate addressable memory locations 310, wherein each location of a DRAM is logically associated with the corresponding location of the other DRAMs. For example, the error correction data at a particular location of the second data storage devices 304 is associated with, and used to correct, the first data at the same locations of the first data storage devices 302. However, other embodiments may not be constrained in such a manner. Also, multiple address locations of the devices 302, 304, 306 may be grouped together for error correction and sparing purposes, so that multiple locations of each device 302, 304, 306 may need to be accessed for any error detection or correction operations to be performed over the multiple locations.

Also depicted in the data memory system 300 is a control circuit 308. Generally, the control circuit 308 is configured to generate the error correction data within the second data storage devices 304 based on the user data. Using the error correction data, the control circuit 308 is capable of correcting at least one error within the user data of the first data storage devices 302. Also, based on the errors being detected and corrected, the control circuit 308 is configured to replace one of the first data storage devices 302 or second data storage devices 304 with one of the third data storage devices 306. The functionality of the control circuit 308 is described in greater detail below.

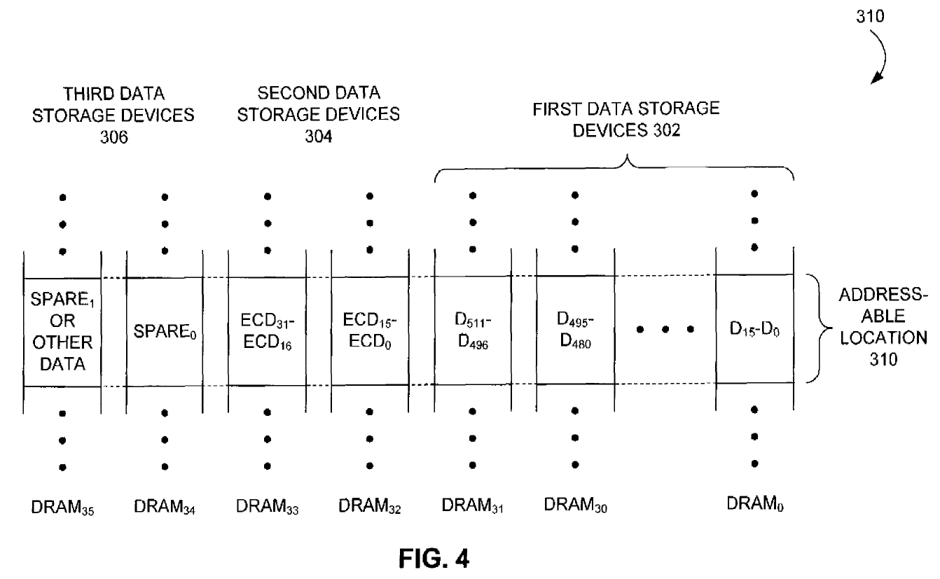

FIG. 4 provides a block diagram of the data organization of one addressable location 310 of the data memory system 300 depicted in FIG. 3. At each location within the first data storage devices 302 are user data D₅₁₁-D₀, resulting in 64 bytes of user data at that location 310. While the following discussion refers to all of these bytes as user data D, other embodiments may employ some of these 64 bytes for control information, status information, and the like, which are protected by the error correction data of the second data storage devices 304 in a fashion similar to that as the user data D. Also, while any control, status, or other information within the first data storage devices 302 may reside in contiguous address locations within the first data storage devices 302, other, more diverse locations within the first data storage devices 302 may be employed for storage of this information in other implementations.

Error correction data ECD for the detection and correction of the user data D within the first data storage devices 302 is stored within the two second data storage devices 304. In the specific example of FIGS. 3 and 4, this configuration results in 32 bits of error correction data (i.e., ECD₃₁-ECD₀) for each addressable location. In one embodiment, the error correction data ECD may be a Reed-Solomon code adapted to detect and correct one or more bits within the user data D or the error correction data ECD itself. Other error correction codes capable of correcting one or more bits within the user data D or the error correction data ECD may be utilized as the error correction data ECD in other implementations.

In addition, some assumptions regarding the most likely types of errors encountered in the particular memory technology employed for the first data storage devices 302 may be made to expedite the error correction process. For example, in the particular example of FIG. 4, which employs DRAM technology, the most likely errors seen in DRAMs, such as temporary errors involving a single bit or small clusters of two or four bits, may be assumed initially to expedite the error detection and correction process. Similarly, if SRAMs are employed for the first data storage devices 302, errors commonly experienced in SRAMs may be assumed instead.

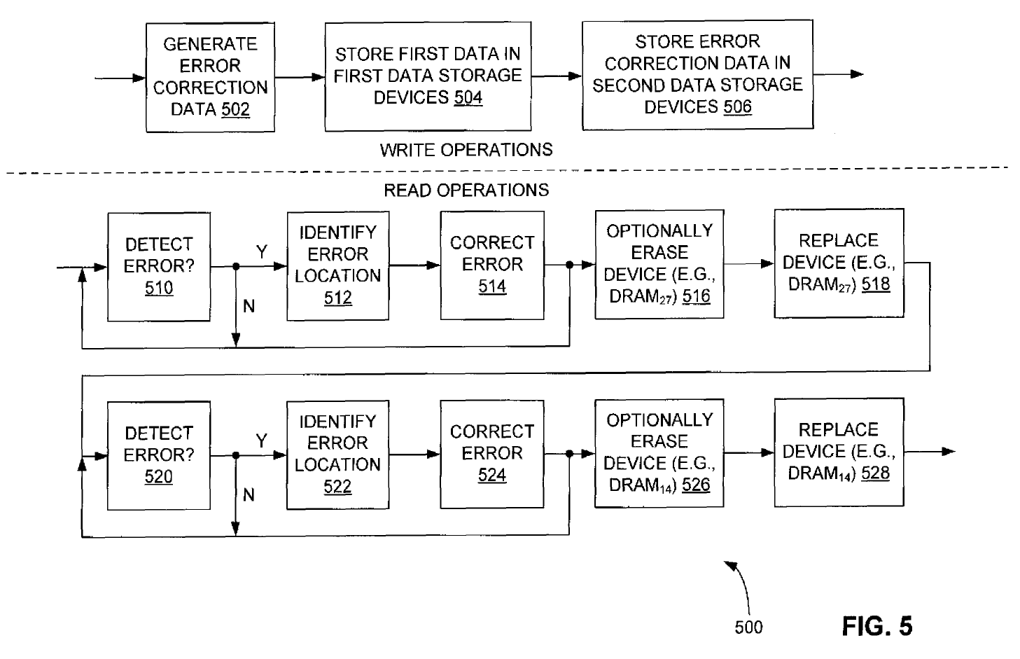

FIG. 5 illustrates by way of a flow diagram various data storage operations (during write operations) and error detection and correction operations (during read operations) of the data memory system 300 according to one embodiment of the invention. For example, as part of a write operation, when the user data D₅₁₁-D₀ is to be written to the location 310 of FIG. 4, the control circuit 308 also generates the error correction data ECD₁₅-ECD₀ for that same location 310 by processing the user data D₅₄₃-D₀ (operation 502).

The user data D₅₁₁-D₀ of the location 310 of the memory system 300 are stored in the plurality of first data storage devices 302 (operation 504), such as DRAM₃₁-DRAM₀ of FIG. 4. As discussed above, while the particular implementation of FIG. 4 shows all of the data within the first data storage devices 302 being user data D, other information, such as status and control information, may also be included in lieu of part of the user data D in other implementations. The error correction data ECD₃₁-ECD₀ are stored in the second data storage devices 304 (operation 506), alternately labeled in FIG. 4 as DRAM₃₃ and DRAM₃₂. Operations 502, 504 and 506 are repeated for each write operation involving the memory system 300. If one of the first or second data storage devices 302, 304 has been replaced by one of the third data storage devices 306, as described in greater detail below, write operations 504, 506 directed to the replaced device 302, 306 are directed instead to the third data storage device 306 acting as the replacement.

As the data at the location 310 of the memory system 300 is subsequently read, the error correction data ECD₁₅-ECD₀ associated with that location 310 is used to determine if any errors in the associated user data D₅₁₁-D₀ or the error correction data ECD₁₅-ECD₀ are present (operation 510). Depending on the particular implementation, serialized or parallelized processing of the user data D₅₁₁-D₀ employing the error correction data ECD₁₅-ECD₀ provides this determination.

If an error is detected within the user data D₅₁₁-D₀, the location of the error is then identified (operation 512). In one embodiment, use of an error correction code, such as a Reed-Solomon code, as the error correction data ECD may directly determine the location of the error. The error may then be corrected by rewriting the actual, erroneous data in first data storage device 302 determined to contain the error with the corrected data (operation 514)

In one implementation, the control circuit 308 reads each addressable location of each portion of the first data storage devices 302 and corrects the errors encountered within, thus performing a “scrubbing” function. Such a function may be performed as a background task while other read and write accesses to the first data storage devices 302 are given a higher priority.

In one embodiment, if the control circuit 308 determines that an inordinate or unexpectedly high number of errors is being detected in one of the first data storage devices 302 (e.g., DRAM₂₇) or second data storage devices 304, the control circuit 308 may optionally cause an “erasure,” or continued regeneration, of all or part of the first data storage device 302 or second data storage device 304 in question (operation 516). For example, if DRAM₂₇ is being erased, each read of data at an addressable location from the first data storage devices 302 and the second data storage devices 304 involves regenerating the data at the same addressable location of DRAM₂₇ using the error correction data ECD and the remaining data in the first data storage devices 302 at the same location of the second data storage devices 304, as described above. As mentioned earlier, error correction data ECD in the form of a Reed-Solomon code or other powerful ECC code may determine the regenerated data directly by calculation

With or without erasure, the control circuit 308 at some point may determine that replacement of the entire first data storage device 302 (in this case, DRAM₂₇) or second data storage device 304 is warranted (operation 518). Such a replacement involves substituting the use of the first data storage device 302 or second data storage device 304 with a selected one of the third data storage devices 306 that is allocated as a spare storage device, as DRAM₃₄, alternately labeled SPARE₀. This replacement may only occur if the selected third data storage device 306 is not already serving as a replacement for another of the first or second data storage devices 302, 304.

In one embodiment, the replacement operation 518 is carried out by reading the data of each location within the first data storage device 302 or second data storage device 304 to be replaced, and inserting the data into the particular third data storage device 306 selected as a spare (i.e., SPARE₀ in this case). Again, such as operation is likely to be performed in a background mode while other, more time-critical, accesses to the first or second data storage device 302, 304 to be replaced are occurring. Also, each read access of the first or second data storage device 302, 304 being replaced may also involve correcting any data errors encountered as a result of the read operation. Furthermore, any write operations to the first or second data storage device 302, 304 while the replacement operation is still in progress should also be reflected in the selected third data storage device 306. Once all of the data has been transferred to the third data storage device 306, data read and write operations intended for the replaced first or second data storage device 302, 304 are instead redirected to, or serviced by, the selected third data storage device 306.

Once replacement by way of one of the third data storage devices 306 has been completed, any erasure of the replaced first or second data storage device 302, 304 may cease, allowing normal error detection and correction of user data D, as well as subsequent erasure of another of the first or second data storage devices 302, 304. As before, the error correction data ECD associated with an addressable location 310 is employed to determine the presence of an error in the associated user data D (operation 520). If such an error is detected, the location of the error within the portion is then identified (operation 522) by way of the error correction data ECD, as described above. The error is then corrected or rewritten according to the error correction data ECD (operation 524), as discussed earlier. If a particular one of the first or second data storage devices 302, 304 is found to be particularly troublesome during read operations, the control circuit 308 optionally may cause an erasure (operation 526) of all or part of the first or second data storage device 302, 304 in question. For example, presuming errors are often located within DRAM₁₄, DRAM₁₄ may be erased by employing the error correction data ECD to always regenerate data read from that particular first data storage device 302, as described earlier. After, or in lieu of, erasure, the troublesome device 302, 304 (i.e., DRAM₁₄) may be replaced by another of the third data storage devices 304 (i.e., DRAM₃₅, labeled SPARE₁), presuming such a device is available for sparing (operation 528). For example, as indicated above, SPARE₁ may instead be employed for another task, such as for containing directory information or additional error correction codes, thus precluding the use of SPARE₁ as a spare device.

As a result, various embodiments of the invention, such as the methods illustrated in FIGS. 2 and 5, and the memory systems 100, 300 of FIGS. 1, 3 and 4, provide the ability to simultaneous replace one or more of the first data storage devices 302 or second data storage devices 304, depending on the number of third data storage devices 306 available as spares, and optionally erase another of the first or second data storage devices 302, 304. In addition, many of these embodiments are easily implemented using a number of JEDEC-standard memory configurations, such as four or more DIMMs each employing 9 memory devices, or two or more DIMMs each including 18 memory devices, as described above.

As noted above, while the memory system 300 of FIGS. 3 and 4 specifically identifies the data storage devices 302, 304, 306 as DRAMs, other data storage devices may be employed while utilizing the various aspects of the embodiments of the invention discussed herein. For example, other widths of DRAMs, such as 8-bit-wide DRAMs, may be employed to similar end, wherein at least one two such DRAMs contain error correction data, and at least one other DRAM is allocated as a spare. Other memory device ICs, such as SRAMs, of varying widths can be employed in a similar fashion. Further, several memory devices, each of which comprise multiple memory ICs, may be organized and utilized in a corresponding manner. For example, SIMMs, DIMMs, and FBDs, each employing DRAMs, SRAMs or other memory ICs, may also be used, wherein at least two such devices may contain error correction, and at least one other serves as a spare. In other implementations, a mixture of any of these or other memory technologies may be employed within a single memory system.

The control circuit 108 of FIG. 1 and the control circuit 308 of FIG. 3 may be realized as a hardware circuit implementing logic necessary to carry out the various operations described herein. In other embodiments, the control circuits 108, 308 may be implemented via one or more processors, such as microprocessors, microcontrollers, and the like, executing software or firmware instructions residing on a storage medium to perform the tasks described above. In still other implementations, the control circuits 108, 308 may entail some combination of hardware and software logic elements.

While several embodiments of the invention have been discussed herein, other embodiments encompassed by the scope of the invention are possible. For example, aspects of one embodiment may be combined with those of other embodiments discussed herein to create further implementations of the present invention. Thus, while the present invention has been described in the context of specific embodiments, such descriptions are provided for illustration and not limitation. Accordingly, the proper scope of the present invention is delimited only by the following claims.

What is claimed is:

1. A data memory system, comprising:
a plurality of first data storage devices configured to store first data;
at least two second data storage devices configured to store error correction data;
a third data storage device; and
a control circuit configured to generate the error correction data using the first data, correct at least one error in the first data using the error correction data, and replace one of the plurality of first data storage devices or one of the at least two second data storage devices with the third data storage device.

2. The data memory system of claim 1, wherein the control circuit is further configured to:
detect a first error in the first data;
identify one of the first data storage devices containing the first error; and
correct the first error in the first data using the error correction data.

3. The data memory system of claim 2, wherein the control circuit is further configured to:
regenerate each of the first data in the one of the first data storage devices containing the first error based on the error correction data.

4. The data memory system of claim 2, wherein the control circuit is further configured to:
replace the one of the first data storage devices containing the first error with the third data storage device;
detect a second error in the first data;
identify a second one of the first data storage devices containing the second error; and
correct the second error in the first data using the error correction data.

5. The data memory system of claim 4, wherein the control circuit is further configured to:
regenerate each of the first data in the one of the first data storage devices containing the second error based on the error correction data.

6. The data memory system of claim 4, further comprising another third data storage device, and wherein the control circuit is further configured to replace the one of the first data storage devices containing the second error with the other third data storage device.

7. The data memory system of claim 1, wherein the first data comprises user data.

8. The data memory system of claim 1, wherein at least one of the plurality of first data storage devices, the second data storage devices, and the third data storage device consists of a dynamic random access memory, a static random-access memory, a single in-line memory module, a dual in-line memory module, and a fully-buffered dual in-line memory module.

9. The data memory system of claim 1, wherein the error correction data comprises a Reed-Solomon code.

10. The data memory system of claim 1, wherein each addressable location of the second data storage devices comprises a portion of the error correction data associated with the same addressable location of the plurality of first data storage devices.

11. A method for storing and correcting data, comprising:
generating error correction data based on first data;
storing the first data in a plurality of first data storage devices;
storing the error correction data in at least two second data storage devices;
correcting at least one error in the first data using the error correction data; and
replacing one of the plurality of first data storage devices or one of the at least two second data storage devices with a third data storage device.

12. The method of claim 11, further comprising:
detecting a first error in the first data;
identifying one of the first data storage devices containing the first error; and
correcting the first error in the first data using the error correction data.

13. The method of claim 11, further comprising:
regenerating each of the first data in the one of the first data storage devices containing the first error based on the error correction data.

14. The method of claim 11, further comprising:
replacing the one of the first data storage devices containing the first error with the third data storage device;
detecting a second error in the first data;
identifying a second one of the first data storage devices containing the second error; and
correcting the second error in the first data using the error correction data.

15. The method of claim 14, further comprising:
regenerating each of the first data in the one of the first data storage devices containing the second error based on the error correction data.

16. The method of claim 14, further comprising:
replacing the one of the first data storage devices containing the second error with another third data storage device.

17. The method of claim 11, wherein the first data comprises user data.

18. The method of claim 11, wherein each addressable location of the second data storage devices comprises a portion of the error correction data associated with the same addressable location of the plurality of first data storage devices.

19. A data storage medium comprising instructions executable on a processor for employing the method of claim 11.

20. A data memory system, comprising:
means for generating error correction data for first data;
multiple means for storing the first data;
first and second means for storing the error correction data;
means for correcting errors in the first data using the error correction data; and
means for replacing one of the multiple means for storing the first data or one of the first and second means for storing the error correction data.
